(19) United States
(12) Patent Application Publication
(10) Pub. No.: US 2016/0312379 A1
(43) Pub. Date: Oct. 27, 2016

(54) MELT GAP MEASURING APPARATUS, CRYSTAL GROWTH APPARATUS AND MELT GAP MEASURING METHOD

(71) Applicant: GlobalWafers Co., Ltd., Hsinchu (TW)

(72) Inventors: Chun-Hung Chen, Hsinchu (TW); Wen-Chieh Lan, Hsinchu (TW); Masami Nakanishi, Hsinchu (TW); Chi-Tse Lee, Hsinchu (TW); Ying-Ru Shih, Hsinchu (TW); Wen-Ching Hsu, Hsinchu (TW)

(21) Appl. No.: 15/076,683

(22) Filed: Mar. 22, 2016

(30) Foreign Application Priority Data
Apr. 23, 2015 (TW) 104113021

(51) Int. Cl. C30B 15/20; C30B 15/30; C30B 29/06; G01B 11/14

(52) U.S. Cl. CPC C30B 15/20; G01B 11/14; C30B 15/30; C30B 29/06

(57) ABSTRACT

A melt gap measuring apparatus is adapted to measure the gap between the bottom of the heat insulating cover and the surface of the raw material melt inside a crucible. The melt gap measuring apparatus includes a first light-guiding probe having a first upper side and a first bottom side which are opposite to each other. The first upper side is exposed to an inner wall of the heat insulating cover, and the first bottom side protrudes from the bottom side of the heat insulating cover. An image capturing device is disposed above the heat insulating cover to capture the image of the first upper side. Moreover, a crystal growth apparatus and a method of measuring the melt gap are also provided.

### CROSS-REFERENCE TO RELATED APPLICATION

This application claims the priority benefit of Taiwan application serial no. 104113021, filed on Apr. 23, 2015. The entirety of the above-mentioned patent application is hereby incorporated by reference herein and made a part of this specification.

### BACKGROUND

1. Field of the Invention

The invention is directed to a crystal growth measuring apparatus of a semiconductor and a method thereof and more particularly, to an apparatus and a method of measuring a gap between a heat insulating cover and a surface of a raw material melt.

2. Description of Related Art

In recent years, the semiconductor industry has been vigorously developed, in which silicon wafers are the most essential necessities of the semiconductor industry. Growing methods of a silicon wafer include a floating zone method, a laser heated pedestal growth method, a Czochralski method (CZ method) and so on. Among them, the CZ method has become the current major growing method for large-sized wafers due to having better economic benefits.

During the growing of a single crystal by utilizing the CZ method, a seed crystal is dipped into raw material melt of silicon retained in a crucible within a chamber maintained in an inert atmosphere under reduced pressure, and the dipped seed crystal is gradually pulled, thereby, a single crystal silicon is grown below the seed crystal. Additionally, in the CZ method, a heat insulating cover in a cylindrical or an inverted conical form has to be disposed around the single crystal silicon to isolate radiant heat to control a temperature gradient of the grown single crystal silicon. Thus, the grown single crystal silicon may be effectively increased under a temperature gradient of a high temperature, which contributes to obtaining a defect-free crystal in a quick speed.

In order to accurately control the temperature gradient of the single crystal, a gap between the heat insulating cover and a surface of the raw material melt of silicon in the crucible has to be precisely controlled within a predetermined distance. However, as for a visual monitoring method by human eyes used at present, it usually leads to large errors, an excessive temperature gradient and breakage, which result in issues, e.g., poor crystal quality.

### SUMMARY

The invention provides a melt gap measuring apparatus including a first light-guiding probe and an image capturing device for measuring a gap between the heat insulating cover and a surface of a raw material melt in a crucible.

The invention provides a crystal growth apparatus capable of controlling a gap between the heat insulating cover and the melt by using the melt gap measuring apparatus, such that the bottom side of the heat insulating cover is prevented from being ablated.

The invention provides a melt gap measuring method capable of capturing changes in an image of the first light-guiding probe by using the image capturing device to control relative positions of the crucible and the heat insulating cover.

According to an embodiment of the invention, a melt gap measuring apparatus is provided. The melt gap measuring apparatus is used to measure a gap between a bottom side of a heat insulating cover and a surface of a raw material melt in a crucible. The melt gap measuring apparatus includes a first light-guiding probe and an image capturing device. The first light-guiding probe has a first upper side and a first bottom side which are opposite to each other. The first upper side is exposed to an inner wall of the heat insulating cover, and the first bottom side protrudes from the bottom side of the heat insulating cover. The image capturing device is disposed above the heat insulating cover and used to capture an image of the first upper side.

According to an embodiment of the invention, a crystal growth apparatus is provided. The crystal growth apparatus includes a cavity, a crystal pulling rod, a crucible, a heating device, a heat insulating cover, a first light-guiding probe and an image capturing device. The crystal pulling rod is disposed in the cavity and used to pull up a seed crystal. The crucible is disposed in the cavity and used to contain the melt. The heating device is disposed in the cavity, located around the crucible and used to heat the melt. The heat insulating cover is disposed in the cavity and located above the crucible. The first light-guiding probe is installed on the bottom side of the heat insulating cover and has a first upper side and a first bottom side which are opposite to each other. The first upper side is exposed to an inner wall of the heat insulating cover, and the first bottom side protrudes from the bottom side of the heat insulating cover. The image capturing device is disposed outside the cavity, located above the heat insulating cover and used to capture an image of the first upper side.

According to an embodiment of the invention, a melt gap measuring method adapted to measure a gap between a bottom side of a heat insulating cover and a surface of a raw material melt in a crucible is provided. The melt gap measuring method includes, during a process of the gap between the crucible and the heat insulating cover being reduced, capturing an image of a first light-guiding probe installed on a bottom side of the heat insulating cover by using an image capturing device and analyzing the captured image to determine whether the first light-guiding probe contacts the surface of the melt; and stopping the gap between the crucible and the heat insulating cover from being reduced when the first light-guiding probe is determined as contacting the surface of the melt upon the analysis of the captured image.

In an embodiment of the invention, the first upper side is spherical, rod-like or plate-like.

In an embodiment of the invention, a material of the first light-guiding probe includes quartz, graphite or silicon.

In an embodiment of the invention, the melt gap measuring apparatus further includes a second light-guiding probe. The second light-guiding probe is installed on the bottom side of the heat insulating cover and has a second top side and a second bottom side which are opposite to each other. The second top side is exposed to the inner wall of the heat insulating cover, and the second bottom side protrudes from the bottom side of the heat insulating cover. A height of the portion of the second light-guiding probe protruding from the bottom side of the heat insulating cover is lower than a height of the portion of the first light-guiding probe protruding from the bottom side of the heat insulating cover.

In an embodiment of the invention, the crystal growth apparatus further includes a thermal insulation device disposed in the cavity. The heating device is located between the thermal insulation device and the crucible.

In an embodiment of the invention, the melt gap measuring method further includes capturing an image of a second light-guiding probe disposed on the bottom side of the heat insulating cover by using the image capturing device, wherein a height of the portion of the second light-guiding probe protruding from the bottom side of the heat insulating cover is lower than a height of the portion of the first light-guiding probe protruding from the bottom side of the heat insulating cover; and controlling the gap between the crucible and the heat insulating cover to obtain a determination result that the first light-guiding probe does not contact the surface of the melt, but the second light-guiding probe contacts the surface of the melt when the captured image is analyzed.

In an embodiment of the invention, the step of analyzing the captured image to determine whether the first light-guiding probe contacts the surface of the melt includes determining whether an amount of color or brightness change of the first light-guiding probe is over a threshold.

To sum up, the melt gap measuring apparatus of the invention is used to measure the gap between the bottom side of the heat insulating cover and the surface of the raw material melt in the crucible. When the light-guiding probe contacts the surface of the melt, the appearance of the light-guiding probe changes. The changes of the appearance image of the light-guiding probe is captured by the image capturing device, such that relative positions of the crucible and the heat insulating cover are accordingly adjusted. Thereby, the gap between the bottom side of the heat insulating cover and the surface of the raw material melt can be maintained within a predetermined range. Through the monitoring of the image capturing device, the invention can achieve avoiding errors due to visual monitoring by human eyes to enhance quality of the grown crystal and improve output efficiency.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating a melt gap measuring apparatus according to an embodiment of the invention.

FIG. 2 is a schematic diagram illustrating a part of elements of the melt gap measuring apparatus according to an embodiment of the invention.

FIG. 3A is a schematic diagram illustrating a part of elements of the melt gap measuring apparatus according to another embodiment of the invention.

FIG. 3B is a schematic cross-sectional diagram illustrating the part of the elements of the melt gap measuring apparatus depicted in FIG. 3A.

FIG. 4 is a schematic diagram illustrating one of the light-guiding probes of the part of the elements of the melt gap measuring apparatus depicted in FIG. 3A.

FIG. 5 is a schematic diagram illustrating a crystal growth apparatus according to an embodiment of the invention.

FIG. 6 is a flowchart illustrating a melt gap measuring method according to an embodiment of the invention.

FIG. 7 is a schematic diagram illustrating a melt gap measuring apparatus according to another embodiment of the invention.

FIG. 8 is a flowchart illustrating a melt gap measuring method according to another embodiment of the invention.

FIG. 9 is a flowchart illustrating a melt gap measuring method according to yet another embodiment of the invention.

### DESCRIPTION OF EMBODIMENTS

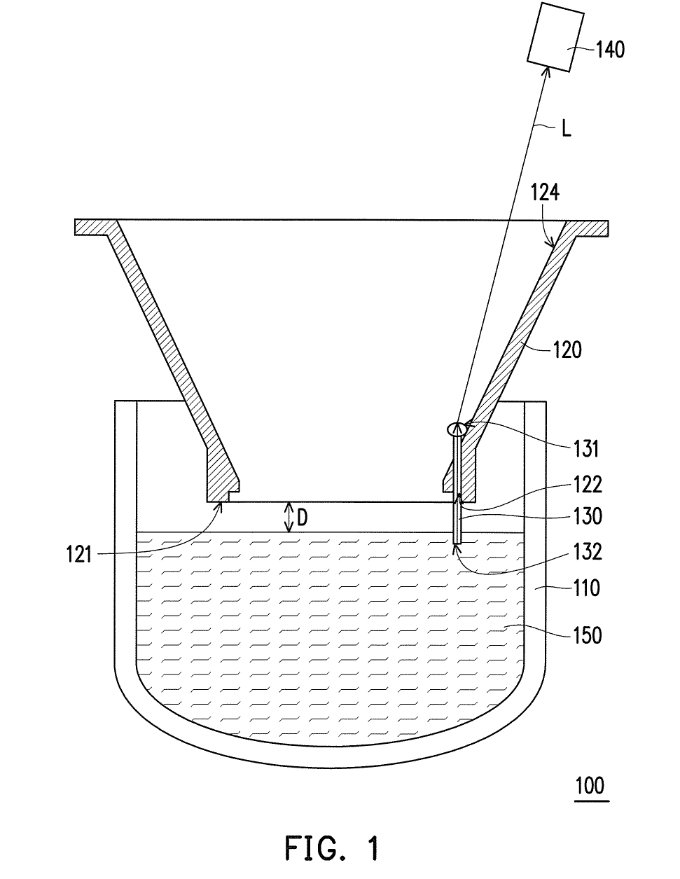

FIG. 1 is a schematic diagram illustrating a melt gap measuring apparatus according to an embodiment of the invention. In the present embodiment, a melt gap measuring apparatus 100 is adapted to measure a gap D between a heat insulating cover 120 and a surface of a melt 150 in a crucible 110. The melt gap measuring apparatus 100 includes a first light-guiding probe 130 and an image capturing device 140. In the present embodiment, the heat insulating cover 120 has a through hole 122, and the through hole 122 extends from an inner wall 124 of the heat insulating cover 120 to a bottom side 121 of the heat insulating cover 120. Additionally, the first light-guiding probe 130 is installed on the heat insulating cover 120 through the through hole 122. The first light-guiding probe 130 has a first upper side 131 and a first bottom side 132 which are opposite to each other. The first upper side 131 is exposed to the inner wall 124 of the heat insulating cover 120 to fix the first light-guiding probe 130 on the heat insulating cover 120. The first bottom side 132 of the first light-guiding probe 130 protrudes from the bottom side 121 of the heat insulating cover 120 and contacts the surface of the melt 150 in the crucible 110 when the crucible 110 lifts up, so as to generate color change. The image capturing device 140 is disposed above the heat insulating cover 120 and captures an image light L and its image change through the first upper side 131 of the first light-guiding probe 130 before and after the first light-guiding probe 130 contacts the melt 150. The image capturing device 140 detects a pixel variation resulted from change in the image color of the first light-guiding probe 130, so as to stop the crucible 110 from lifting up to prevent the bottom side 121 of the heat insulating cover 120 from being ablated by a high temperature of the melt 150. Additionally, the prevention of the bottom side 121 of the heat insulating cover 120 from being ablated by the melt 150 may further facilitate in preventing impurities which are generated from the ablated heat insulating cover 120 from polluting the melt, so as to enhance quality of crystal growing. It should be noted that the pixel variation described in the present embodiment includes changes in image brightness and colors.

In the present embodiment, the image capturing device 140 is, for example, a charge-coupled device (CCD) image sensor. The first light-guiding probe 130 is made of a material, such as quartz, graphite or silicon (Si). In the present embodiment, the material of the first light-guiding probe 130 is described as quartz, for example. Referring to FIG. 1, in the crucible 110, a polycrystalline silicon material is melted in a high temperature, i.e., a temperature over the melting point of silicon materials, 1420° C., to form a silicon melt 150. Furthermore, the color change occurs to the first light-guiding probe 130 made of quartz when contacting the melt 150. The image capturing device 140 captures the image change occurring when the first bottom side 132 of the first light-guiding probe 130 contacts the melt 150, so as to detect the pixel variation resulted from the image change.

In the present embodiment, the image capturing device 140 measures and defines the gap D between the bottom side 121 of the heat insulating cover 120 and the melt 150 through directly detecting whether the first bottom side 132 of the first light-guiding probe 130 contacts the surface of the melt 150. In the present embodiment, the gap D between the bottom side 121 of the heat insulating cover 120 and the melt 150 is not calculated and defined through the image capturing device 140 detecting a mirror image position of the first light-guiding probe 130 on the surface of the melt 150 and further according to the minor image position, and thus, measurement errors may be effectively reduced in the present embodiment in comparison with the method requiring the detection of the mirror image position. Therefore, the gap D between the bottom side 121 of the heat insulating cover 120 and the melt 150 may be measured and controlled more precisely, so as to prevent the bottom side 121 of the heat insulating cover 120 from contacting the high-temperature surface of the melt 150.

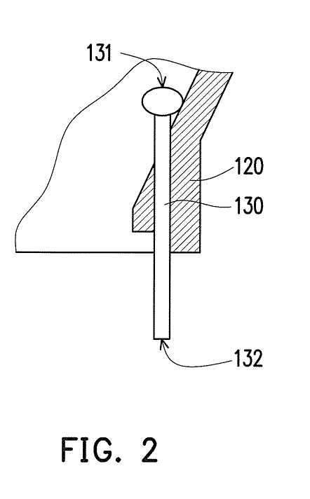

FIG. 2 is a schematic diagram illustrating a part of elements of the melt gap measuring apparatus according to an embodiment of the invention. Referring to FIG. 1 and FIG. 2, in the present embodiment, the heat insulating cover 120 is made of, for example, a graphite material. The heat insulating cover 120 is capable of isolating radiant heat during a crystal pulling process of a single crystal silicon (not shown), so as to control and increase a temperature gradient of the single crystal silicon. Specially, in a high-temperature environment, the increase of the temperature gradient of the single crystal silicon is in favor of quick formation of defect-free single crystal silicon. Additionally, in the present embodiment, when the first bottom side 132 of the first light-guiding probe 130 contacts the surface of the melt 150, the first light-guiding probe 130 generates the image change to the first upper side 131 of the first light-guiding probe 130 by means of light guiding and reflection. Moreover, in the design of relative positions of the first light-guiding probe 130 and the image capturing device 140, a light transmittance part of the first light-guiding probe 130 faces the image capturing device 140, such that the image capturing device 140 captures the image change of the first light-guiding probe 130.

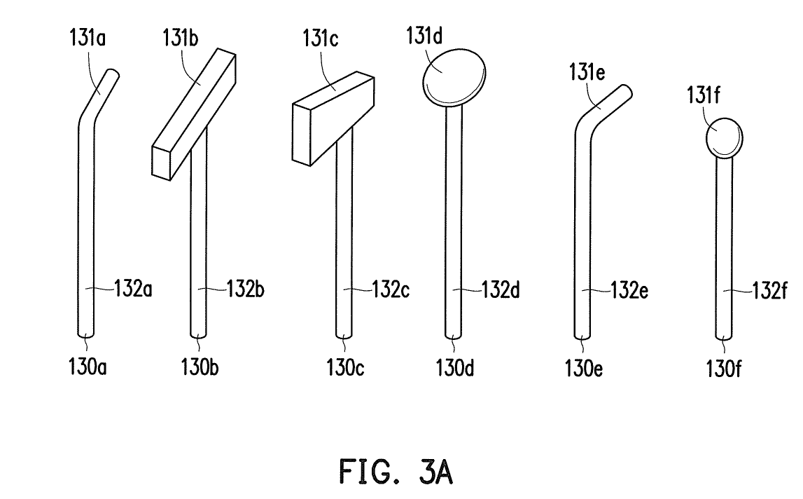

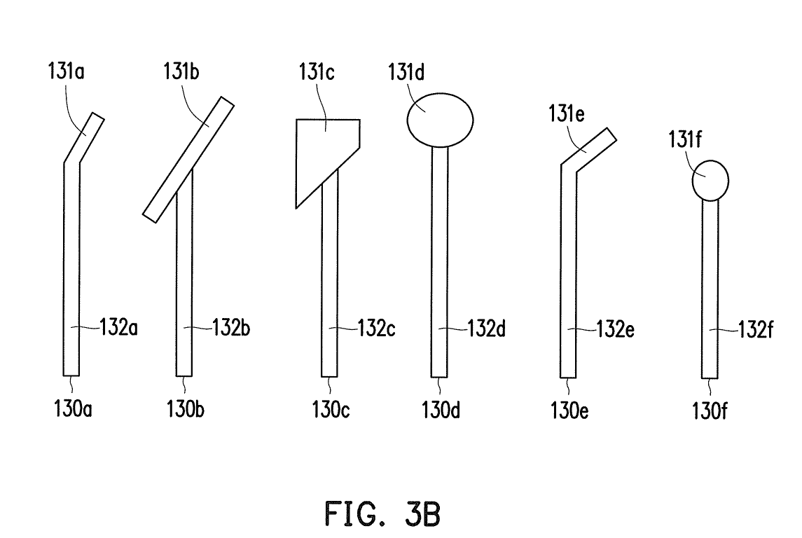

FIG. 3A is a schematic diagram illustrating a part of elements of the melt gap measuring apparatus according to another embodiment of the invention. FIG. 3B is a schematic cross-sectional diagram illustrating the part of the elements of the melt gap measuring apparatus depicted in FIG. 3A. Referring to FIG. 3A and FIG. 3B, in the present embodiment, the melt gap measuring apparatus 100 may select different types of first light-guiding probes 130a, 130b, 130c, 130d, 130e and 130f according to actual demands for light guiding and light reflecting paths, where the first light-guiding probes 130a, 130b, 130c, 130d, 130e and 130f respectively have first upper sides 131a, 131b, 131c, 131d, 131e, 131f and first bottom sides 132a, 132b, 132c, 132d, 132e and 132f. For example, the first upper side 131a, 131b, 131c, 131d, 131e and 131f are spherical, rod-like or plate-like or other suitable shapes. It should be mentioned that taking the first upper sides 131a and 131e of the first light-guiding probes 130a and 130e for example, the first upper sides 131a and 131e have different tilting angles with respect to the first bottoms side 132a and 132e to generate different light guiding and reflection effects. Certainly, other different types of light-guiding probes may also be used based on other light guiding needs in the present embodiment and are not particularly limited in the present embodiment.

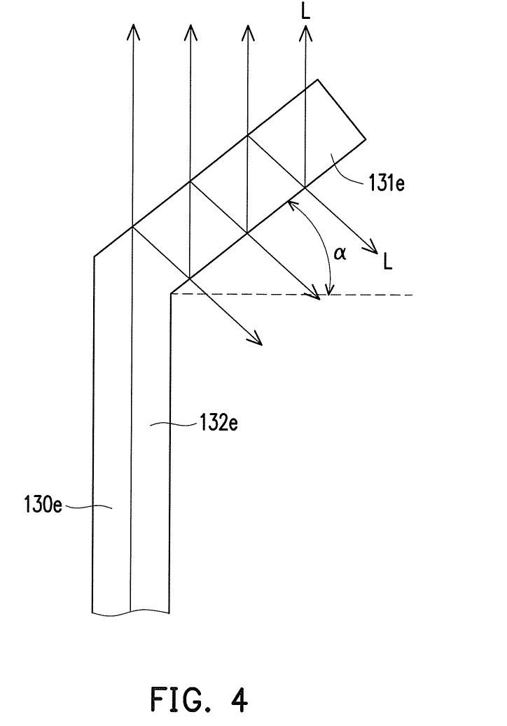

FIG. 4 is a schematic diagram illustrating one of the light-guiding probes of the part of the elements of the melt gap measuring apparatus depicted in FIG. 3A. In FIG. 4, the first light-guiding probe 130e illustrated in FIG. 3A is taken as an example for illustrating a travelling path of the image light L in the first light-guiding probe 130e. When the first bottom side 132e of the first light-guiding probe 130e contacts the high-temperature surface of the melt 150, a color of the first light-guiding probe 130e changes. Then, the image light L generated after the color change is guided and reflected by the first light-guiding probe 130e and enters the first upper side 131e through the first bottom side 132e of the first light-guiding probe 130e. In the present embodiment, an extending direction of the first upper side 131e has an included angle a with respect to a surface vertical to the first bottom side 132e. The included angle a may be designed as falling within a range from 15 degrees to 40 degrees to generate total reflection of the image light L in the first upper side 131e, such that the image capturing device 140 captures an image of the first light-guiding probe 130e through the first upper side 131e. For example, the included angle a is illustrated as 20 degrees in the present embodiment.

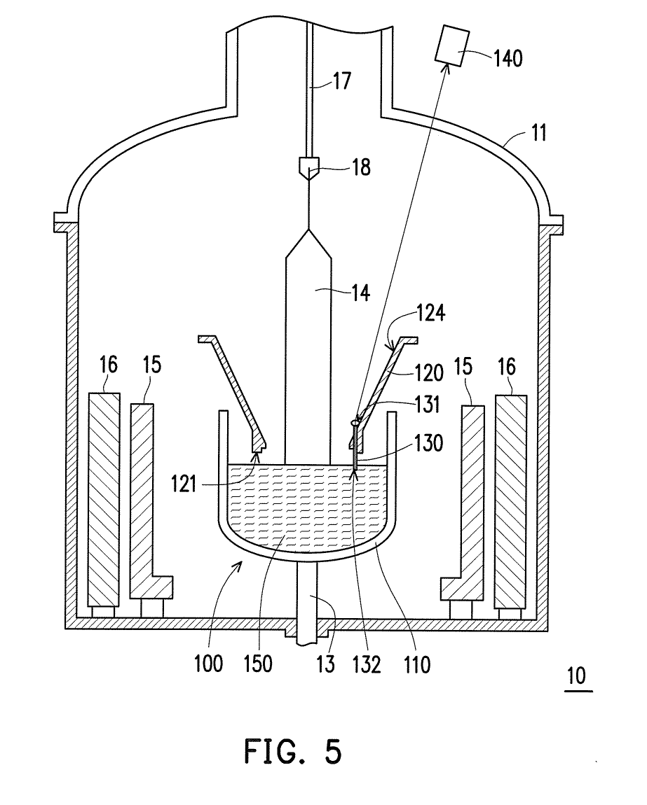

FIG. 5 is a schematic diagram illustrating a crystal growth apparatus according to an embodiment of the invention. A crystal growth apparatus 10 includes a cavity 11, and the melt gap measuring apparatus 100 is disposed in the cavity 11. In addition, the crystal growth apparatus 10 includes a heating device 15 and a thermal insulation device 16. The heating device 15 is disposed in the cavity 11, located around the crucible 110 of the melt gap measuring apparatus 100 and used to heat the melt 150 in the crucible 110. The thermal insulation device 16 is also disposed in the cavity 11, and the heating device 15 is located between the thermal insulation device 16 and the crucible 110 to maintain the temperature of the melt 150 and the heated effect resulted by the heating device 15. In addition, a crystal pulling rod 17 is disposed above the crucible 110 and used to pull up a seed crystal 18. A rotary rod 13 disposed under the crucible 110 supports the crucible 110 and drives the crucible 110 to rotate. In the present embodiment, a semiconductor material, e.g., polycrystalline silicon and a dopant of, for example, boron or phosphorous, are melted at a high temperature more than or equal to 1420° C. in the crucible 110 to form the melt 150. When the polycrystalline silicon material and the dopant are melted, the crystal pulling rod 17 is slowly put down into the melt 150. Then, the crystal pulling rod 17 rotates counterclockwise, and the crucible 110 is driven by the rotary rod 13 to rotate clockwise. The seed crystal 18 is pulled by the crystal pulling rod 17, such that a cylinder-like silicon brick 14 is formed under the seed crystal 18. In the present embodiment, the crystal growth apparatus 10 monitors the gap between the surface of the melt 150 and the heat insulating cover 120 by the image capturing device 140 disposed outside the cavity 11 and thereby, controls the quality of crystal growing.

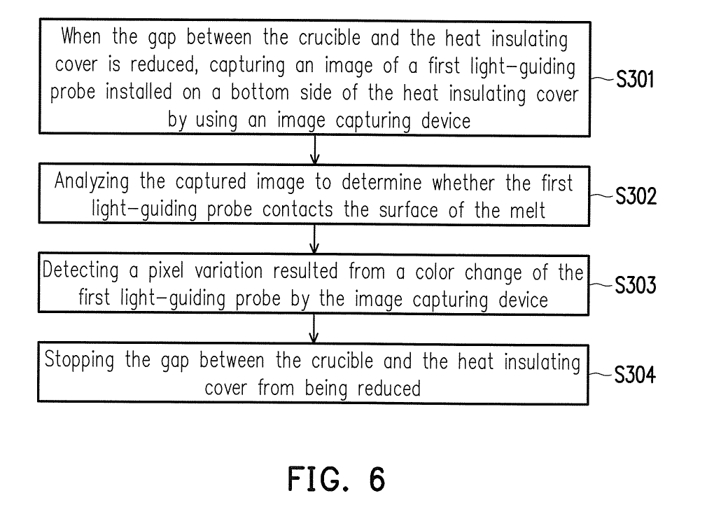

FIG. 6 is a flowchart illustrating a melt gap measuring method according to an embodiment of the invention. Referring to FIG. 1 and FIG. 6, in the present embodiment, when the gap D between the crucible 110 and the heat insulating cover 120 is reduced, an image of the first light-guiding probe installed on the bottom side 121 of the heat insulating cover 120 is captured by the image capturing device 140 (step S301). Then, the captured image is analyzed to determine whether the first light-guiding probe 130 contacts the surface of the melt 150 (step S302). Thereafter, the image capturing device 140 detects a pixel variation resulted from the color change of the first light-guiding probe 130 (step S303). When the pixel variation is detected by the image capturing device 140, the gap D between the crucible 110 and the heat insulating cover 120 is stopped from being reduced (step S304), so to prevent the high-temperature surface of the melt 150 from further approaching the bottom side 121 of the heat insulating cover 120 which may cause the ablation to the heat insulating cover 120.

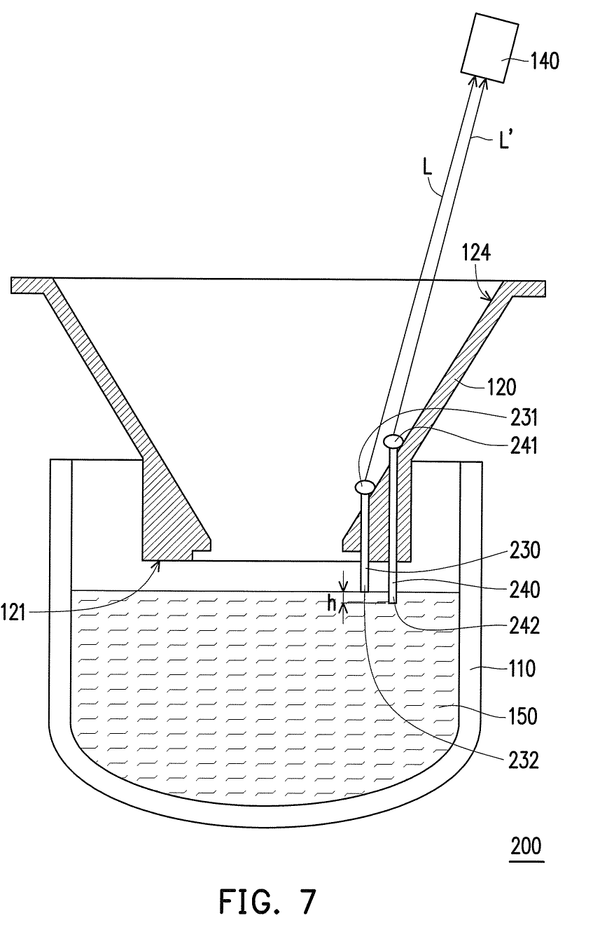

FIG. 7 is a schematic diagram illustrating a melt gap measuring apparatus according to another embodiment of the invention. A melt gap measuring apparatus 200 illustrated in FIG. 7 has a similar structure like that of the melt gap measuring apparatus 100 illustrated in FIG. 1, and thus, the same or similar elements are labeled by the same or similar symbols, which will not be repeatedly described. In the present embodiment, the difference between the melt gap measuring apparatus 200 and the melt gap measuring apparatus 100 illustrated in FIG. 1 lies in the melt gap measuring apparatus 200 simultaneously having a first light-guiding probe 230 and a second light-guiding probe 240, where the first light-guiding probe 230 and the second light-guiding probe 240 are disposed in parallel to each other. In the present embodiment, the first light-guiding probe 230 has a first upper side 231 and a first bottom side 232, and the second light-guiding probe 240 has a second top side 241 and a second bottom side 242. The first upper side 231 and the second top side 241 are respectively exposed to the inner wall 124 of the heat insulating cover 120, and the first bottom side 232 and the second bottom side 242 respectively protrude from the bottom side of the heat insulating cover 120. In the present embodiment, a height difference h is between the part of the first bottom side 232 protruding from bottom side of the heat insulating cover 120 and the part of the second bottom side 242 protruding from the bottom side of the heat insulating cover 120. Specifically, referring to FIG. 7, a height of the part of the second bottom side 242 protruding from the bottom side 121 of the heat insulating cover 120 is lower than a height of the part of the first bottom side 232 protruding from the bottom side 121 of the heat insulating cover 120. Additionally, the image capturing device 140 of the present embodiment simultaneously detects an image light L from the first upper side 231 and an image light L′ from the second top side 241. In the present embodiment, the gap between the bottom side 121 of the heat insulating cover 120 and the surface of the melt 150 may be monitored more precisely by means of the disposition of the first light-guiding probe 230 and the second light-guiding probe 240. In addition, in comparison with the embodiment that only one light-guiding probe is disposed, the present embodiment achieves not only preventing the bottom side 121 of the heat insulating cover 120 from being ablated due to the surface of the melt 150 being overly high through the disposition of the first light-guiding probe 230 and the second light-guiding probe 240, but also maintaining the surface of the melt 150 between the first bottom side 232 of the first light-guiding probe 230 and the second bottom side 242 of the second light-guiding probe 240 by means of the adjustment of the relative positions of the heat insulating cover 120 and the crucible 110. Thus, a scenario that the surface of the melt 150 is overly low may be prevented in the present embodiment, so as to enhance the quality of crystal growing.

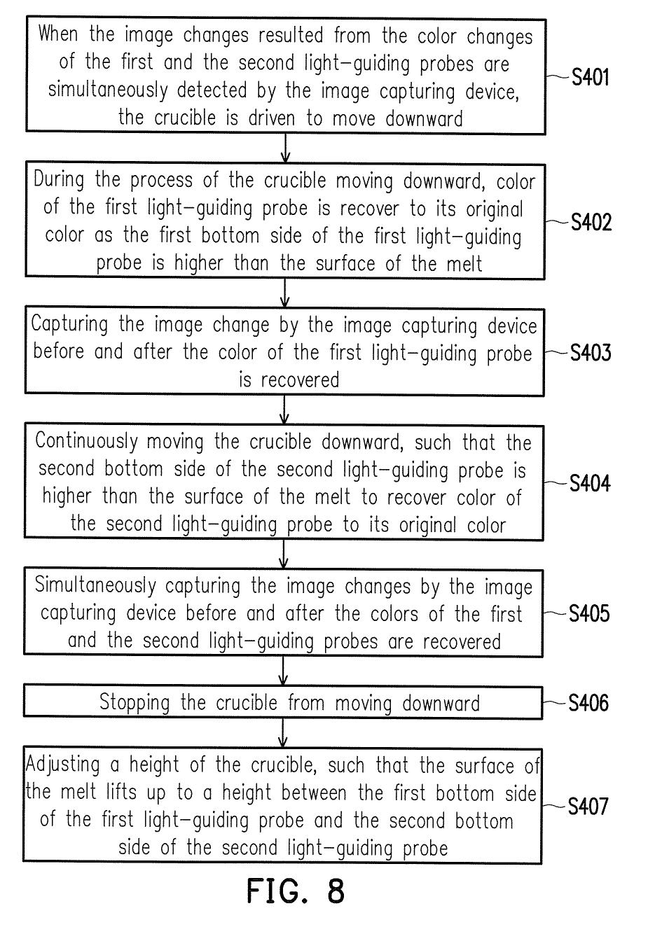

FIG. 8 is a flowchart illustrating a melt gap measuring method according to another embodiment of the invention. Referring to FIG. 7 and FIG. 8, for instance, when the image capturing device 140 simultaneously detects image changes after the colors of the first and the second light-guiding probes 230 and 240 change, the crucible 110 is driven to move downward (step S401). During the process of the crucible 110 moving downward, color of the first light-guiding probe 230 is recovered to its original color due to the first bottom side 232 of the first light-guiding probe 230 departing from the surface of the melt 150 (step S402). Then, the image capturing device 140 captures the image change before and after the color of the first light-guiding probe 230 is recovered (step S403). Then, the crucible 110 is continuously moved downward, such that the second bottom side 242 of the second light-guiding probe 240 is higher than the surface of the melt 150 to recover color of the second light-guiding probe 240 to its original color (step S404). Then, the image capturing device 140 simultaneously captures the image changes before and after the colors of the first and the second light-guiding probes 230 and 240 are recovered (step S405). At this time, the crucible 110 is stopped from moving downward (step S406). At last, a height of the crucible 110 is adjusted, such that the surface of the melt 150 lifts up to a height between the first bottom side 232 of the first light-guiding probe 230 and the second bottom side 242 of the second light-guiding probe 240 (step S407). Although the heat insulating cover 120 is fixed while the crucible 110 is moved in the present embodiment for example; however, the crucible 110 may be moved while the heat insulating cover 120 may be fixed, or both the crucible 110 and the heat insulating cover 120 may be moved in other embodiments.

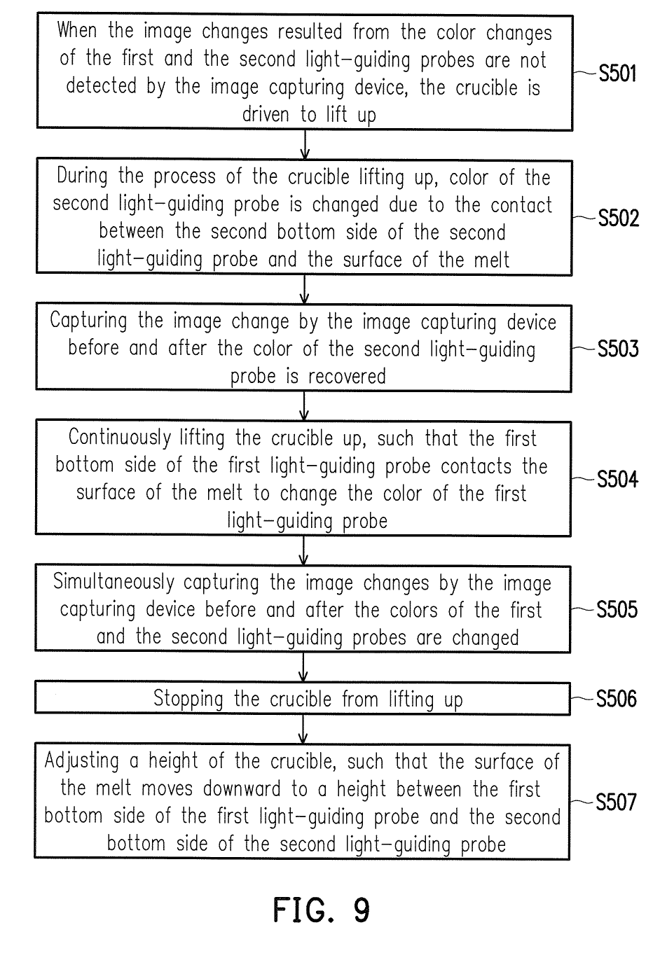

FIG. 9 is a flowchart illustrating a melt gap measuring method according to yet another embodiment of the invention. Referring to FIG. 7 and FIG. 9, if the image capturing device 140 is in an initial state, and the image changes resulted from the color changes of the first and the second light-guiding probes 230 and 240 are not detected (i.e., the surface of the melt 150 is lower than the heights of the first and the second bottom sides 232 and 242), the crucible 110 is driven to lift up (step S501). During the process of the crucible 110 lifting up, the second bottom side 242 of the second light-guiding probe 240 first contacts the surface of the melt 150 to generate the color change (step S502). Then, the image capturing device 140 captures the image change before and after the color of the second light-guiding probe 240 changes (step S503). Then, the crucible 110 continues to lift up, such that the first bottom side 232 of the first light-guiding probe 230 also contacts the surface of the melt 150 to generate the color change (step S504). Thus, the image capturing device 140 simultaneously captures the image changes before and after the colors of the first and the second light-guiding probes 230 and 240 change (step S505). At this time, the crucible 110 stops lifting up (step S506). At last, the height of the crucible 110 is adjusted, such that the surface of the melt 150 moves downward to a height between the first bottom side 232 and the second bottom side 242.

In the previous embodiment, the images of the first and the second light-guiding probes 230 and 240 installed on the bottom side 121 of the heat insulating cover 120 are captured by the image capturing device 140, and the gap between the crucible 110 and the heat insulating cover 120 is controlled, such that a determination result that the first light-guiding probe 230 does not contact the surface of the melt 150, but the second light-guiding probe 240 contacts the surface of the melt 150 is obtained when the captured image is analyzed. Furthermore, the determination operation whether the first light-guiding probe 130 contacts the surface of the melt 150 when the captured image is analyzed is performed to determine whether an amount of the color or brightness change of the first light-guiding probe 130 is over a set threshold. The height of the melt 150 may be controlled to be between the first bottom side 232 and the second bottom side 242 through the first light-guiding probe 230, the second light-guiding probe 240 and the image capturing device 140 continuously monitoring the position of the surface of the melt 150 relative to the heat insulating cover 120, such that the position of the surface of the melt 150 may be prevented from being too high or too low, and the single crystal silicon achieves a preferable growth state.

To summarize, the melt gap measuring apparatus of the invention is utilized to measure the gap between the bottom of the heat insulating cover and the surface of the melt in the crucible. When the light-guiding probe contacts the surface of the melt, the color change occurs to the light-guiding probe due to the high temperature of the melt. The image capturing device senses the image change before the color changes and accordingly, adjusts the relative positions of the crucible and the heat insulating cover, so as to maintain the gap between the bottom of the heat insulating cover and the surface of the raw material melt in a predetermined range to prevent the bottom side of the heat insulating cover from being ablated by the melt. In the invention, the monitoring performed by the image capturing device can contribute to avoiding the errors resulted from visual monitoring by human eyes and prevent breakage occurring due to overly large or small gap between the crucible and the heat insulating cover, such that the quality of crystal growing can be enhanced, and the output efficiency can be improved.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A melt gap measuring apparatus, adapted to measure a gap between a bottom side of a heat insulating cover and a surface of a melt in a crucible, the melt gap measuring apparatus comprising:
a first light-guiding probe, installed on the bottom side of the heat insulating cover and having a first upper side and a first bottom side which are opposite to each other, wherein the first upper side is exposed to an inner wall of the heat insulating cover, and the first bottom side protrudes from the bottom side of the heat insulating cover; and
an image capturing device, disposed above the heat insulating cover and used to capture an image of the first upper side.

2. The melt gap measuring apparatus according to claim 1, wherein the first upper side is spherical, rod-like or plate-like.

3. The melt gap measuring apparatus according to claim 1, wherein a material of the first light-guiding probe comprises quartz, graphite or silicon.

4. The melt gap measuring apparatus according to claim 1, further comprising:
a second light-guiding probe, installed on the bottom side of the heat insulating cover and having a second top side and a second bottom side which are opposite to each other, wherein the second top side is exposed to the inner wall of the heat insulating cover, the second bottom side protrudes from the bottom side of the heat insulating cover, a height of the portion of the second light-guiding probe protruding from the bottom side of the heat insulating cover is lower than a height of the portion of the first light-guiding probe protruding from the bottom side of the heat insulating cover.

5. A crystal growth apparatus, comprising:
a cavity;
a crystal pulling rod, disposed in the cavity and used to pull up a seed crystal;
a crucible, disposed in the cavity and used to contain a melt;
a heating device, disposed in the cavity, located around the crucible and used to heat the melt;
a heat insulating cover, disposed in the cavity and located above the crucible;
a first light-guiding probe, installed on the bottom side of the heat insulating cover, and having a first upper side and a first bottom side which are opposite to each other, wherein the first upper side is exposed to an inner wall of the heat insulating cover, and the first bottom side protrudes from the bottom side of the heat insulating cover; and
an image capturing device, disposed outside the cavity, located above the heat insulating cover and used to capture an image of the first upper side.

6. The crystal growth apparatus according to claim 5, wherein the first light-guiding probe comprises quartz, graphite or silicon.

7. The crystal growth apparatus according to claim 5, wherein the first upper side is spherical, rod-like or plate-like.

8. The crystal growth apparatus according to claim 5, further comprising:
a thermal insulation device, disposed in the cavity, wherein the heating device is located between the thermal insulation device and the crucible.

9. A melt gap measuring method for measuring a gap between heat insulating cover and a surface of a melt in a crucible, the melt gap measuring method comprising:
during a process of the gap between the crucible and the heat insulating cover being reduced, capturing an image of a first light-guiding probe installed on a bottom side of the heat insulating cover by using an image capturing device and analyzing the captured image to determine whether the first light-guiding probe contacts the surface of the melt; and
stopping the gap between the crucible and the heat insulating cover from being reduced when the first light-guiding probe is determined as contacting the surface of the melt upon the analysis of the captured image.

10. The melt gap measuring method according to claim 9, further comprising:
capturing an image of a second light-guiding probe disposed on the bottom side of the heat insulating cover by using the image capturing device, wherein a height of the portion of the second light-guiding probe protruding from the bottom side of the heat insulating cover is lower than a height of the portion of the first light-guiding probe protruding from the bottom side of the heat insulating cover; and
controlling the gap between the crucible and the heat insulating cover to obtain a determination result that the first light-guiding probe does not contact the surface of the melt, but the second light-guiding probe contacts the surface of the melt when the captured image is analyzed.

11. The melt gap measuring method according to claim 9, wherein the step of analyzing the captured image to determine whether the first light-guiding probe contacts the surface of the melt comprises:
determining whether an amount of color or brightness change of the first light-guiding probe is over a threshold.
